(19) United States
(12) Patent Application Publication
(10) Pub. No.: US 2012/0008650 A1
(43) Pub. Date: Jan. 12, 2012

(54) HYBRID INTEGRATED TUNEABLE LASER

(75) Inventors: Alistair James Poustie, Ipswich Suffolk (GB); Graeme Douglas Maxwell, Ipswich Suffolk (GB); David William Smith, Woodbridge (GB); Richard Wyatt, Woodbridge (GB)

(73) Assignee: The Centre For Integrated Photonics Limited, Ipswich Suffolk (GB)

(21) Appl. No.: 13/256,068

(22) PCT Filed: Mar. 12, 2010
(86) PCT No.: PCT/GB2010/050436

§ 371 Date: Sep. 12, 2011

(30) Foreign Application Priority Data
Mar. 12, 2009 (GB) 0904247.4

(51) Int. Cl. H01S 5/14

(52) U.S. Cl. 372/20

(57) ABSTRACT

A hybrid integrated tuneable optical laser device, suitable for tuning to different wavelengths via a piezo micromotor (6) controlled optical filter (4) in an external cavity. Once the laser is fixed at a selected wavelength, no power is required to be applied to the wavelength tuning element to maintain the wavelength stability.

The present invention relates to a wavelength tuneable laser.

### BACKGROUND

External cavity tuneable lasers (ECLs) can be constructed from an active gain element, an optical coupling mechanism, a wavelength selective optical element and an optical feedback element, see for example U.S. Pat. No. 5,331,651. Many tuneable ECLs use an optical diffraction grating as the combined wavelength selective and feedback element and the mechanical position of this grating is used to control the lasing wavelength. Three-axis control of the grating is usually required to maintain the laser wavelength and the optimum lasing feedback condition. It is also known that incorporating a thin film filter in the external cavity can allow a selection of a number of longitudinal laser modes in the laser cavity, see for example P. Zorabedian and W. R. Trutna, Jr., “Interference-filter-tuned, alignment-stabilized, semiconductor external-cavity laser,” Opt. Lett. 13, p.826 (1988).

### BRIEF SUMMARY OF THE DISCLOSURE

In accordance with the present invention there is provided a wavelength tuneable, single longitudinal mode external cavity laser device comprising a substrate material, a semiconductor optical amplifier gain medium, a collimating lens, and a reflective element arranged relative to the gain medium to form a laser cavity, wherein the device further comprises a single narrowband thin-film coated filter interposed in the optical path between the gain medium and the reflective element, whereby the laser wavelength is tuneable by adjusting the angle of the thin-film filter to said optical path.

Thus, the invention provides, at least in preferred embodiments, a wavelength tuneable laser that operates on a single longitudinal mode and the single-mode wavelength is determined by single axis angle tuning of a narrowband thin-film coated filter in the cavity. In embodiments of the invention only a single thin-film coated filter may be interposed in the optical path between the gain medium and the reflective element.

The laser device may comprise a mechanism to adjust mechanically the angle of the thin-film filter to said optical path. For example, the device may comprise an electrically powered motor (in particular a piezo-micro motor) arranged to adjust the angle of the thin-film filter to the optical path. The adjustment mechanism may be configured to maintain the angular position of the filter to the optical path in the absence of electrical power to the motor. Thus, according to embodiments of the invention, the mechanical tuning of the filter is achieved with a compact piezo micromotor that does not require any electrical power to be applied to maintain the lasing wavelength. Such piezo micromotors are readily available, for example for use in the focussing mechanisms of digital cameras.

The thin-film filter may be provided on a filter substrate that is thermally matched to the narrowband thin-film coating. The thin-film filter may be provided on a plane parallel filter substrate.

Thermal compensation of the thin-film coated filter with the substrate material also allows the laser to maintain wavelength with varying temperatures. These features allow the laser to return to the previously set wavelength after all electrical power is removed then reapplied which is a feature that has not been possible with previous tuneable laser designs.

One or more of the gain medium, the collimating lens, the reflective element and the filter may be located mechanically on the substrate material by locating formations defined lithographically on the substrate material. Complementary locating formations may be formed on the gain medium, the reflective element and/or the filter. Thus, in embodiments of the invention, the optical pieceparts of the laser are aligned by passive alignment techniques to greatly reduce the packaging cost of the tuneable laser.

The optical mode field within the semiconductor optical amplifier gain medium may be expanded before exiting an output facet of the amplifier.

Thus, there is disclosed herein a wavelength tuneable external cavity laser featuring a semiconductor optical amplifier gain medium where single longitudinal mode operation and wavelength are determined by a single thin-film coated filter. The wavelength tuning may be achieved by mechanically angle-tuning the thin-film coated filter. In a preferred arrangement, the nominal operating wavelength remains set even after electrical power is removed from the mechanism used to adjust the angle of thin film filter. The wavelength tuning may be achieved by mechanically angle tuning the thin-film coated filter with a piezo-micromotor. The thin-film coated filter may be on a thermally matched substrate to reduce the variation in laser wavelength with temperature. The thin-film coated filter may be on a plane parallel thermally matched substrate to maintain laser cavity alignment with angle. The optical elements may fit into precision locations which have been defined by lithographic techniques and formed into a suitable substrate material such as silicon. Variations in the normal incidence wavelength of the grown thin-film coated filter may be compensated by varying the angle of incidence of the filter. Adjustment of the laser wavelength over a restricted wavelength range is possible by small adjustments of the current into the semiconductor optical amplifier gain medium. The mode field within the semiconductor optical amplifier is expanded before exiting the amplifier output facet.

### BRIEF DESCRIPTION OF THE DRAWINGS

Embodiments of the invention are further described hereinafter with reference to the accompanying drawings, in which:

FIG. 1 is a schematic representation showing the component parts of an external cavity tuneable laser according to an embodiment of the invention;

FIG. 2 is a chart of a calculation showing how the central wavelength of the thin-film optical filter varies with angle of incidence; and

FIG. 3 is a chart showing the measured composite spectrum for a laser tuned to different wavelengths via filter angle.

### DETAILED DESCRIPTION

According to an embodiment of the invention, as shown in FIG. 1, a laser cavity is formed between one facet of a broadband semiconductor gain element 1 and a reflective element 5. The value of reflectivity of the semiconductor gain element facet is controlled by the deposition of thin-film coatings onto the chip facet. The reflectivity of the other facet of the semiconductor gain element 1 is minimised by using optical mode expansion, an angled waveguide to the facet and thin-film coatings. The gain element 1 has precision etched features to allow the chip to be passively aligned to a silicon carrier 3. The reflective element 5 at the other end of the cavity can incorporate thin-film coatings to control the reflectivity value. This reflectivity can also be wavelength selective if required. The reflective element 5 is aligned via precision mechanical stops on the silicon carrier 3.

In addition to the semiconductor gain element 1, the laser cavity contains a lens 2 to collimate the output light from the gain element 1 into the external cavity. The lens 2 can be a precision sized ball lens with anti-reflection coatings, suitable for passive assembly with the silicon etched carrier 3. The collimated light passes through a thin-film coated filter element 4 that is a narrow passband filter (FWHM-50 GHz) deposited on a thermally matched substrate (optical glass F7). The bandwidth of the filter 4 is sufficiently narrow, typically less than 0.5 nm (FWHM, single pass) that only a few longitudinal modes of the laser lie within the filter passband and hence single-mode operation of the laser is favoured.

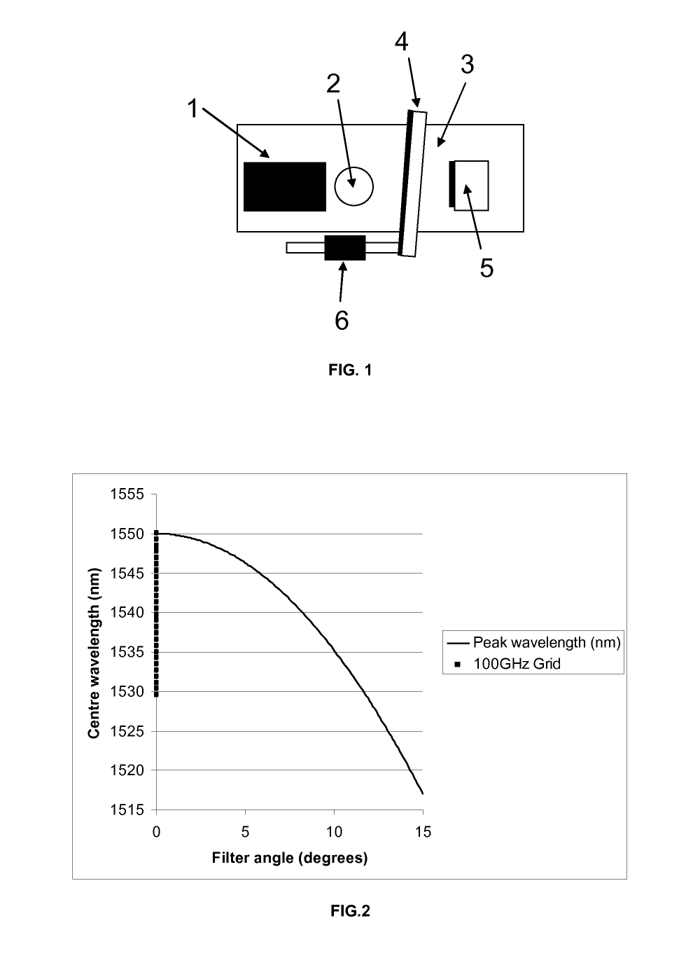

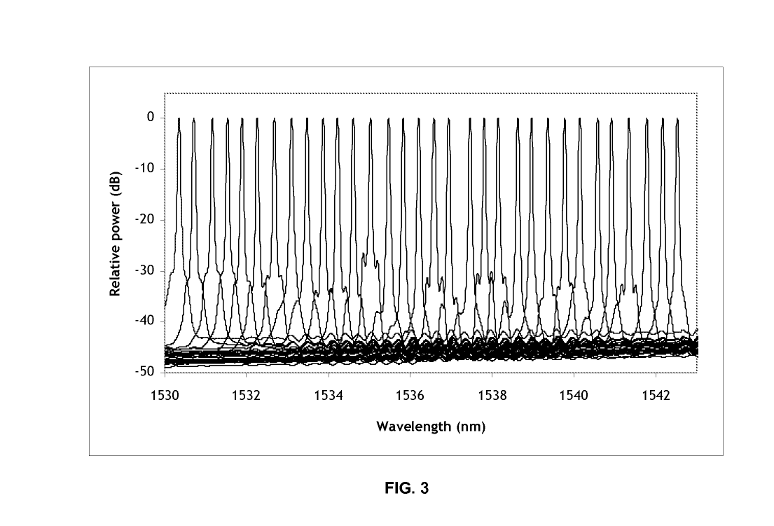

The centre wavelength of the filter 4 varies with angle of incidence as shown in FIG. 2 and the filter angle is used to tune the laser wavelength. The angle of the filter element is controlled mechanically via a compact, single axis piezo-micromotor 6 that has the feature of positional stability when the power is removed from the micromotor 6. Thus, once the filter angle has been set to determine the laser wavelength, the power can be removed from the micromotor 6 and the laser will remain at the determined wavelength. This aspect greatly reduces the overall electrical power requirement for the laser. The filter substrate is plane parallel with an antireflection coating on the opposite side from the filter. This allows simplified alignment of the filter element in the laser cavity by maintaining the angular alignment of the beam in the external cavity. In addition, any small variations in the normal incidence wavelength of the manufactured thin-film filter element can be compensated for by tuning each individual laser filter to different angles. This reduction in manufacturing accuracy for the thin-film filter wavelength greatly increases the yield and hence reduces the cost of the overall laser assembly.

For some applications which require the laser wavelength to be adjusted by small amounts to allow the laser to be either locked precisely to an external reference source or track other wavelength sensitive components in a system an additional method of fine tuning can be included in the embodiment. This fine tuning can typically achieved by making small changes of bias current to the active gain block 1. For an indium phosphide (InP) based reflective semiconductor optical amplifier of 2.7 mm length a bias current adjustment of 1 mA can change the laser frequency by the order of 100 MHz.

Thus, in general terms, there is disclosed herein a hybrid integrated tuneable optical laser device, and in particular one suitable for tuning to different wavelengths via a piezo micromotor controlled optical filter in an external cavity. Once the laser is fixed at a selected wavelength, no power is required to be applied to the wavelength tuning element to maintain the wavelength stability. Applications are expected in telecommunications and sensors.

The invention, at least in the preferred embodiment goes beyond the prior art by using a piezo-micromotor to control the laser wavelength via a single optical filter, to thermally stabilise the lasing wavelength and to achieve low power operation once the wavelength is set.

Throughout the description and claims of this specification, the words “comprise” and “contain” and variations of them mean “including but not limited to”, and they are not intended to (and do not) exclude other components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

1. A wavelength tuneable, single longitudinal mode external cavity laser device comprising a substrate material, a semiconductor optical amplifier gain medium, a collimating lens, and a reflective element arranged relative to the gain medium to form a laser cavity, wherein the device further comprises a single narrowband thin-film coated filter interposed in the optical path between the gain medium and the reflective element, whereby the laser wavelength is tuneable by adjusting the angle of the thin-film filter to said optical path.

2. A laser device as claimed in claim 1 comprising a mechanism to adjust mechanically the angle of the thin-film filter to said optical path.

3. A laser device as claimed in claim 2 comprising a motor, in particular a piezo micromotor, arranged to adjust the angle of the thin-film filter to said optical path.

4. A laser device as claimed in claim 2, wherein the adjustment mechanism is configured to maintain the angular position of the filter to the optical path in the absence of electrical power to the motor.

5. A laser device as claimed in claim 1, wherein one or more of the gain medium, the reflective element and the filter, are located mechanically on the substrate material by locating formations defined lithographically on the substrate material.

6. A laser device as claimed in claim 1, wherein the narrowband thin-film filter is provided on a filter substrate that is thermally matched to the thin-film filter coating.

7. A laser device as claimed in claim 6, wherein the thin-film filter is provided on a plane parallel filter substrate.

8. A laser device as claimed in claim 1, wherein the thin film filter passband is less than 0.5 nm FWHM

9. A laser device as claimed in claim 1, wherein the mode field within the semiconductor optical amplifier gain medium is expanded before exiting an output facet of the amplifier.
